(19) United States
(12) Patent Application Publication
(10) Pub. No.: US 2021/0057323 A1
(43) Pub. Date: Feb. 25, 2021

(54) GROOVE DESIGN TO FACILITATE FLOW OF A MATERIAL BETWEEN TWO SUBSTRATES

(71) Applicant: Intel Corporation, Santa Clara, CA (US)

(72) Inventor: Si Wen LIN, Xiamen, Fujian (CN)

(21) Appl. No.: 17/052,908

(22) PCT Filed: Sep. 28, 2018
(86) PCT No.: PCT/CN2018/108163

§ 371 Date: Nov. 4, 2020

(51) Int. Cl. H01L 23/498; H01L 23/00

(52) U.S. Cl. CPC H01L 23/49833; H01L 2924/15311; H01L 24/14; H01L 24/11

(57) ABSTRACT

Systems, apparatuses, processing (1400), and techniques related to applying a plurality of grooves in a portion of a surface of a first substrate (1402) and coupling a surface of a second substrate to the surface of the first substrate, wherein a selected design of the grooves is to facilitate a flow of a material to fill a volume between the first substrate surface and a second substrate surface (1404).

### TECHNICAL FIELD

Embodiments of the present disclosure generally relate to the field of package assemblies, and in particular package assemblies with material flowed between multiple coupled substrates.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

Continued reduction in end product size of mobile electronic devices such as smart phones and ultrabooks is a driving force for the development of reduced size systems in package components. Package components may involve coupling surfaces together, for example coupling dies to substrates, substrate patches to substrate interposers, and the like.

### BRIEF DESCRIPTION OF THE DRAWINGS

FIGS. 1A-1B illustrate a side view and a top view of a coupled interposer substrate and patch substrate with epoxy to flow between them, in accordance with embodiments.

FIGS. 2A-2B illustrate a top view and a side view of an interposer with grooves to enhance epoxy flow, in accordance with embodiments.

FIG. 3 illustrates a top view of epoxy flow rate acceleration along a direction of the grooves, in accordance with embodiments.

FIG. 4 illustrates a top view of epoxy flow rate deceleration orthogonal to a direction of the grooves, in accordance with embodiments.

FIG. 5 illustrates examples of epoxy flow rate along a direction of grooves with varying groove spacing, in accordance with embodiments.

FIG. 6 illustrates examples of epoxy flow rate perpendicular to a direction of grooves with varying groove spacing, in accordance with embodiments.

FIG. 7 illustrates examples of groove layout on a substrate with various ball grid array (BGA) layout patterns with a positioning of an epoxy dot, in accordance with embodiments.

FIG. 8 illustrates an example of a substrate surface onto which grooves are to be formed in the creation of multiple packages, in accordance with embodiments.

FIG. 9 illustrates examples of creating and using a rod array jig to create grooves in the substrate as a part of creating multiple packages, in accordance with embodiments.

FIG. 10 shows multiple views of a solder resist substrate with grooves resulting from the use of a rod array jig in the creation of multiple packages, in accordance with embodiments.

FIG. 11 shows a top-down view of the solder resist substrate after a developing process in the creation of multiple packages, in accordance with embodiments.

FIG. 12 shows a top-down view of an interposer patch attach area of an example package, in accordance with embodiments.

FIG. 13 shows a top-down view of a solder resist surface with grooves, multiple dies, and epoxy dot, in accordance with embodiments

FIG. 14 illustrates an example process to couple two substrates with a flow of material between them, in accordance with embodiments

FIG. 15 is a schematic of a computer system 1500, in accordance with an embodiment of the present invention.

### DETAILED DESCRIPTION

Embodiments of the present disclosure may generally relate to flowing a material, such as an epoxy, between two coupled substrate surfaces so that the epoxy either completely or substantially fills a volume between the two surfaces, where the height in the volume between the two surfaces may vary. In particular, embodiments may relate to applying a plurality of grooves in a portion of a surface of a first substrate and coupling a surface of a second substrate to the surface of the first substrate, where a selected design of the grooves is to facilitate a flow of a material to fill a volume between the first substrate surface and a second substrate surface.

In legacy implementations, various surfaces substrates, or other surfaces, to be coupled may not be truly coplanar due to surface warpage. As a result, the volume formed between the coupled surfaces may vary in height. This may result in uneven epoxy underflow between the two surfaces due to the speed of the epoxy underflow depending on the height of the volume. This uneven epoxy underflow may result in epoxy voids in the volume. These voids may result in an increase in the baseline yield loss of packages during assembly and test. These voids, particularly when a die is applied to patch substrate, may further result in warpage within the package when further coupled with an interposer substrate. This may result in poor reliability performance, or even failure of the package.

A big volume height difference may induce an imbalance in the epoxy flow speed, and therefore introduce epoxy voids when epoxy is flowed in the volume. A fast epoxy flow speed may result at edge of the coupled surfaces due to smaller gap height and a slower epoxy flow speed may result in the middle where there may be a larger gap height. Defects resulting from epoxy voids may continue to be a challenge as margins become smaller with future processors, and as various warpage tolerances and/or Z-height requirements of packages change.

Legacy implementations to address these issues may include incorporating a high-pressure vacuum machine to minimize epoxy flow defects, or tightening substrate coplanar tolerance criteria from manufacturers and/or suppliers. These approaches, while possibly being effective, may have the disadvantages of assembly cost increases due to additional dedicated machinery introduced into the assembly process, increasing cycle time, and/or increasing substrate cost per unit.

In embodiments, the grooves on the substrate surface may not impact product reliability performance because the grooves may be substantially within an epoxy spreading and/or coverage area.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the figures, and sizes, thicknesses, or dimensions may be assumed for some embodiments only where specifically indicated or discussed.

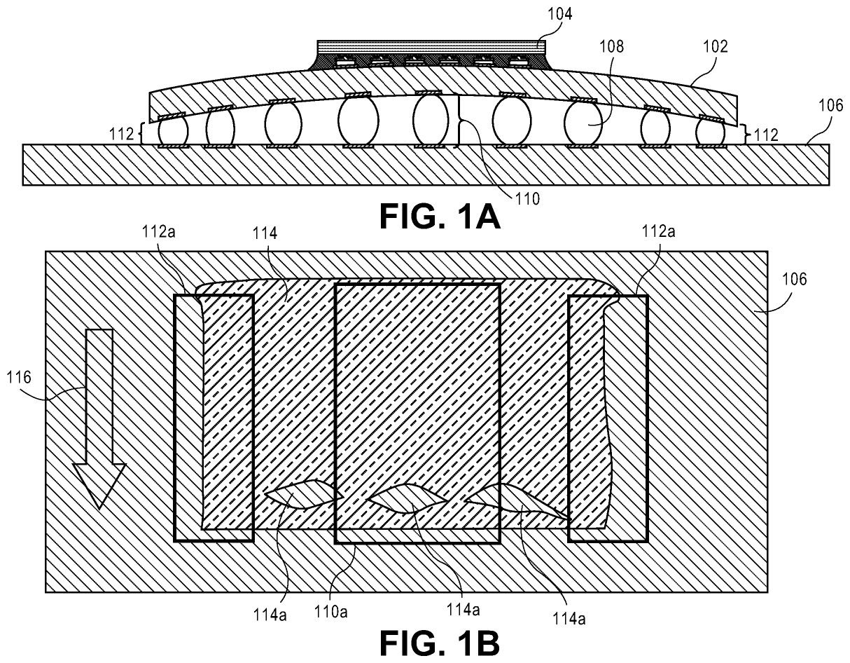

FIGS. 1A-1B illustrate a side view and a top view of a coupled interposer substrate and patch substrate with epoxy to flow between them, in accordance with embodiments. FIG. 1A shows a side view of a patch substrate 102 which may have a die 104 coupled to a side of the patch substrate 102. The patch substrate 102 is coupled to an interposer substrate 106 via a plurality of solder balls 108. In embodiments, the solder balls 108 may also electrically couple the patch substrate 102 and the interposer substrate 106. The patch substrate 102 is non-coplanar with respect to the interposer substrate 106. In other embodiments, each substrate may not be planar yet have some degree of warpage with respect to another substrate. As a result, the height of a gap at a location between the overlap of the surfaces of the patch substrate 102 and the interposer substrate 106 may vary. For example, there may be a larger gap height 110 in a middle area of an overlap and a smaller gap height 112 at the edges of the overlap.

FIG. 1B shows a top-down view where epoxy 114 is flowing between patch substrate 102 (not shown) and interposer substrate 106 in a flow direction 116. In embodiments, the epoxy 114 may be any material that is to be flowed between any two coupled surfaces. The small gap height areas 112a may correspond to epoxy flow near the smaller gap height 112, and the large gap height area 110a may correspond to epoxy flow near the larger gap height 110. The epoxy flow near the smaller gap height 112 may be a faster flow due to capillary action increased by the smaller distance between the surfaces. As a result of the faster flow, epoxy in the large gap height area 110a may be pulled toward the small gap height areas 112a and away from the large gap height area 110a. Slower epoxy 114 flow will result in the large gap height area 100a due to a lessened capillary action. Thus, there may be an insufficient quantity of epoxy 114 in the large gap height area 110a, and epoxy voids 114a may form after the epoxy 114 hardens or otherwise cures. In addition, air or gas may be trapped in the large gap height area 110a due to slower epoxy 114 flow in the large gap height area 110a.

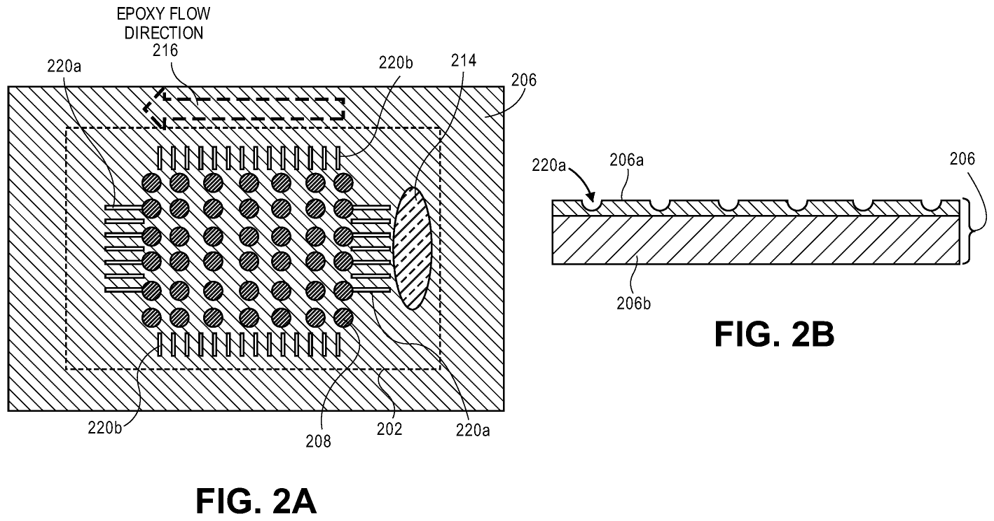

FIGS. 2A-2B illustrate a top view and a side view of an interposer with grooves to enhance epoxy flow, in accordance with embodiments. FIG. 2A illustrates an interposer substrate 206, which may be similar to interposer substrate 106 of FIG. 1A, with solder balls 208, which may be similar to solder balls 108 of FIG. 1A, attached to the substrate 206. In embodiments, the solder balls 208 may be ball grid array pad openings. An epoxy dot 214, which may be similar to epoxy 114 of FIG. 1A, is placed on the interposer substrate 206. The epoxy 214 to flow in epoxy flow direction 216. The patch substrate attach area 202, to which a patch substrate 102 of FIG. 1A may be attached, is shown by a dashed line. The patch substrate attach area 202 may also correspond to an epoxy coverage area once the epoxy dot 214 has completed flowing in the epoxy flow direction 216.

Grooves 220a, 220b may be placed into the surface of the interposer substrate 206. In embodiments, the grooves 220a, 220b may have a “U” shape, a “V” shape, trench shape, or other shape that will effect epoxy 214 to flow. In embodiments, the grooves 220a, 220b may be microgrooves. In embodiments, a microgroove may be a groove having a width in the range of 10 μm to 50 μm, and a depth in the range of 5 μm to 15 μm. In embodiments, these dimensions may vary depending upon the type of surface and composition of epoxy 214. In embodiments, the grooves 220a, 220b may be within a solder resist layer of a substrate surface, as shown in FIG. 2B. The grooves 220a, 220b facilitate eliminating epoxy voids defects by balancing an epoxy 214 flow rate between small gap height areas 112a and large gap height area 110a of FIG. 1B.

In particular, grooves 220a oriented along epoxy flow direction 216 are to increase the epoxy 214 flow speed in the middle of the large gap height area 110a. This may be accomplished through the capillary effects of the grooves 220a to further pull the epoxy 214 forward in the epoxy flow direction 216. The grooves 220b oriented orthogonally to the epoxy flow direction 216 are intended to slow down the epoxy 214 flow rate in the small gap height areas 112a, which may, in embodiments, correspond to an edge area of the patch substrate 102 of FIG. 1B. The grooves 220b may play the role of blocking channels to slow down epoxy flow rate by having to fill the groves 220b first before the epoxy 214 moves in the epoxy flow direction 216. In embodiments, the grooves 220a, 220b may prevent epoxy void defects from forming by a groove design that balances epoxy flow speeds throughout the underflow area by increasing flow rates at the large gap height area 110a and reducing flow rates small gap height areas 112a.

FIG. 2B shows a side view of interposer substrate 206 that has a solder resist layer 206a into which grooves 220a may be made. An example of a layer below the solder resist layer 206a may include a copper (Cu) layer 206b.

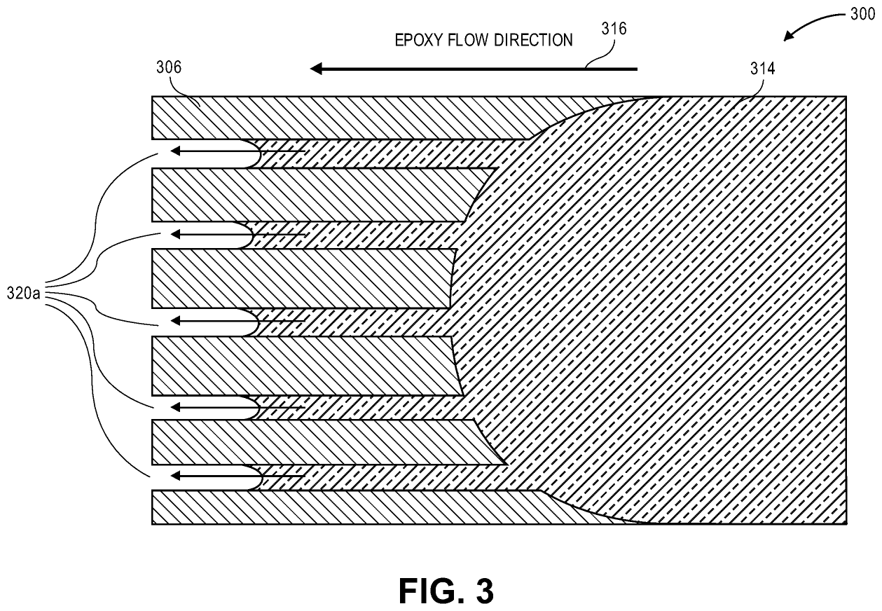

FIG. 3 illustrates a top view of epoxy flow rate acceleration along a direction of the grooves, in accordance with embodiments. Diagram 300 shows an interposer substrate 306, which may be similar to interposer substrate 206 of FIG. 2A, and epoxy 314, which may be similar to epoxy 214 of FIG. 2A, flowing in an epoxy flow direction 316 along grooves 320a, which may be similar to grooves 220a of FIG. 2A. The capillary action resulting from the flow of the epoxy 314 down grooves 320a may accelerate the flow of epoxy 314 in the epoxy flow direction 316.

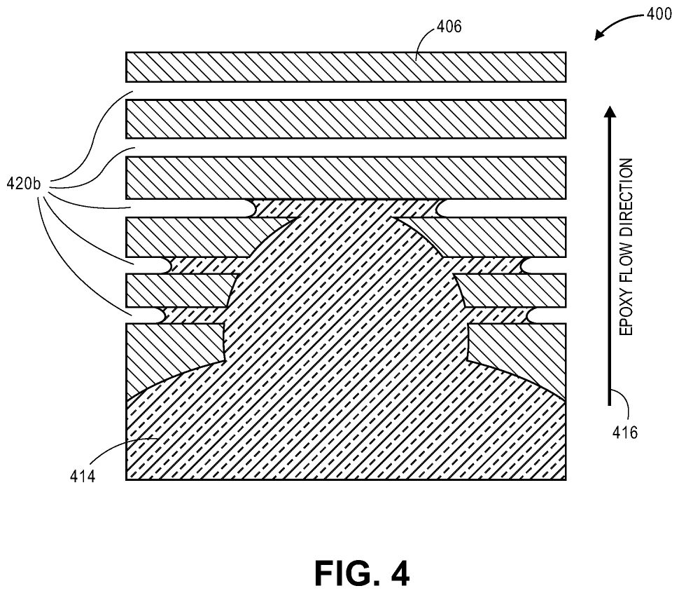

FIG. 4 illustrates a top view of epoxy flow rate deceleration orthogonal to a direction of the grooves, in accordance with embodiments. Diagram 400 shows an interposer substrate 406, which may be similar to interposer substrate 206 of FIG. 2A, and epoxy 414, which may be similar to epoxy 214 of FIG. 2A, flowing in an epoxy flow direction 416 orthogonal to grooves 420b, which may be similar to grooves 220b of FIG. 2A. A flow of the epoxy 414 along the direction of the grooves 420b will slow the overall flow of the epoxy 414 in the epoxy flow direction 416.

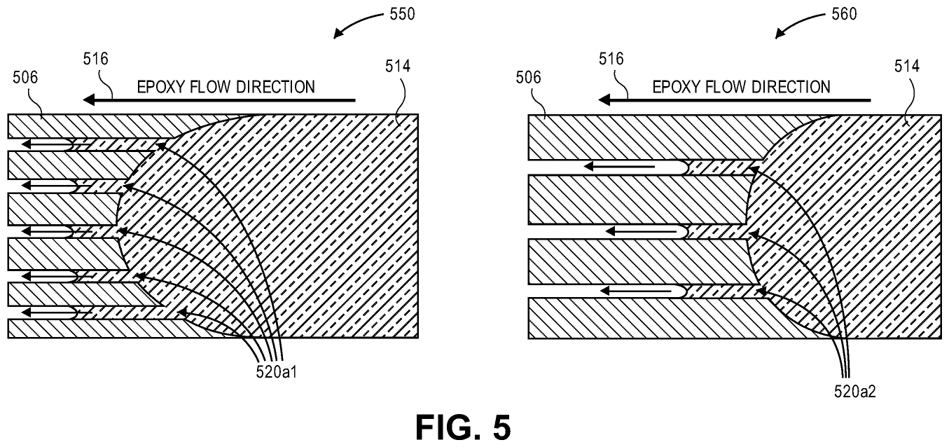

FIG. 5 illustrates examples of epoxy flow rate along a direction of grooves with varying groove spacing, in accordance with embodiments. Diagram 550 shows an interposer substrate 506, which may be similar to interposer substrate 206 of FIG. 2A, and epoxy 514, which may be similar to epoxy 214 of FIG. 2A, that is flowing in an epoxy flow direction 516 parallel to grooves 520a1, which may be similar to grooves 220a of FIG. 2A. The grooves 520a1 are spaced closer together than the grooves 520a2 of diagram 560. As a result, the flow rate of the epoxy 514 in diagram 550 is greater than in diagram 560. In embodiments, this may be due to the increased capillary action of the grooves 520a1 that are spaced closer together.

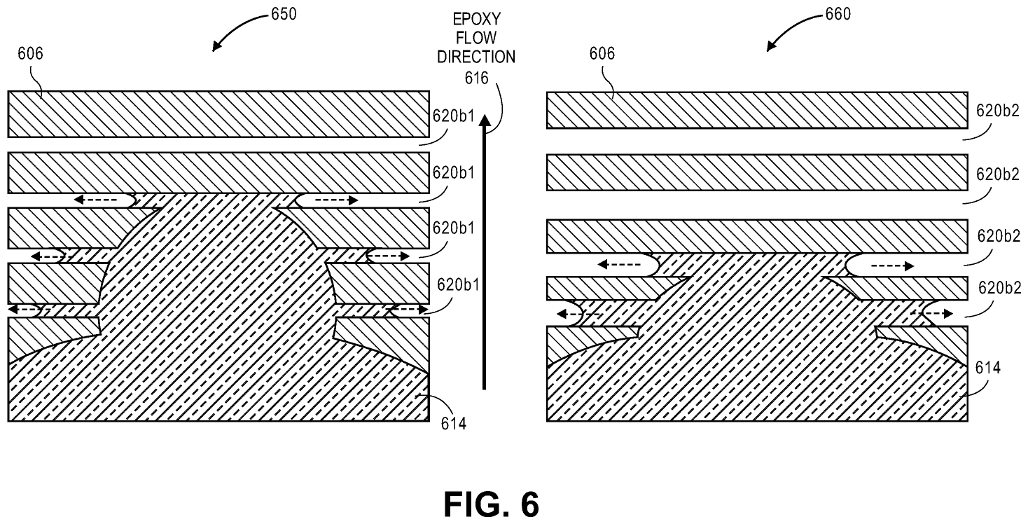

FIG. 6 illustrates examples of epoxy flow rate perpendicular to a direction of grooves with varying groove spacing, in accordance with embodiments. Diagram 650 shows an interposer substrate 606, which may be similar to interposer substrate 206 of FIG. 2A, and epoxy 614, which may be similar to epoxy 214 of FIG. 2A, that is flowing in an epoxy flow direction 616 that is orthogonal to grooves 620b1, which may be similar to grooves 220b of FIG. 2A. The grooves 620b1 of diagram 650 are spaced closer together than the grooves 620b2 of diagram 660. As a result, the flow rate of the epoxy 614 in diagram 660 may be less than the epoxy flow rate in diagram 650.

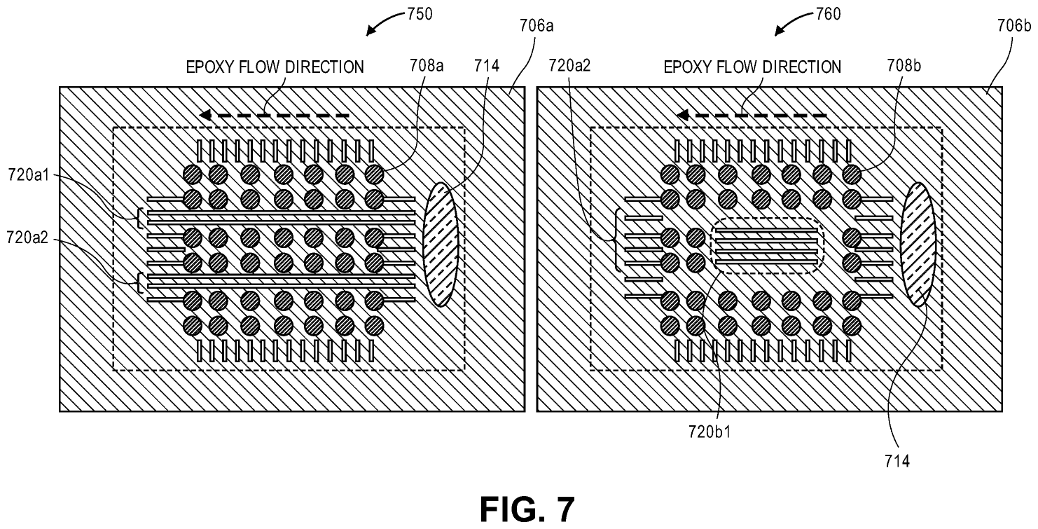

FIG. 7 illustrates examples of groove layout on a substrate with various BGA layout patterns with a positioning of an epoxy dot, in accordance with embodiments. Diagrams 750 and 760, which both may be similar to the figure shown in FIG. 2A, shows two different layouts of a BGA 720a and/or bump pads 720b and also different layouts of groove patterns 720a1, 720a2. These different groove designs may be maximized for epoxy 714 flow in two different layout designs of BGA, or bump pads on interposer substrates 706a, 706b.

In diagram 750, a full BGA 708a is shown with grooves 720a1 and 720a2 between rows of the BGA 708a to encourage a higher flow of epoxy 714 through areas proximate to the grooves 720a1 and 720a2. In diagram 760, grooves 720b1 are placed in an area where there are an absence of bump pads 708b. Epoxy 714 is to flow at a greater rate proximate to groves 720b1 to ensure no voids are created in the area after the epoxy 714 cures.

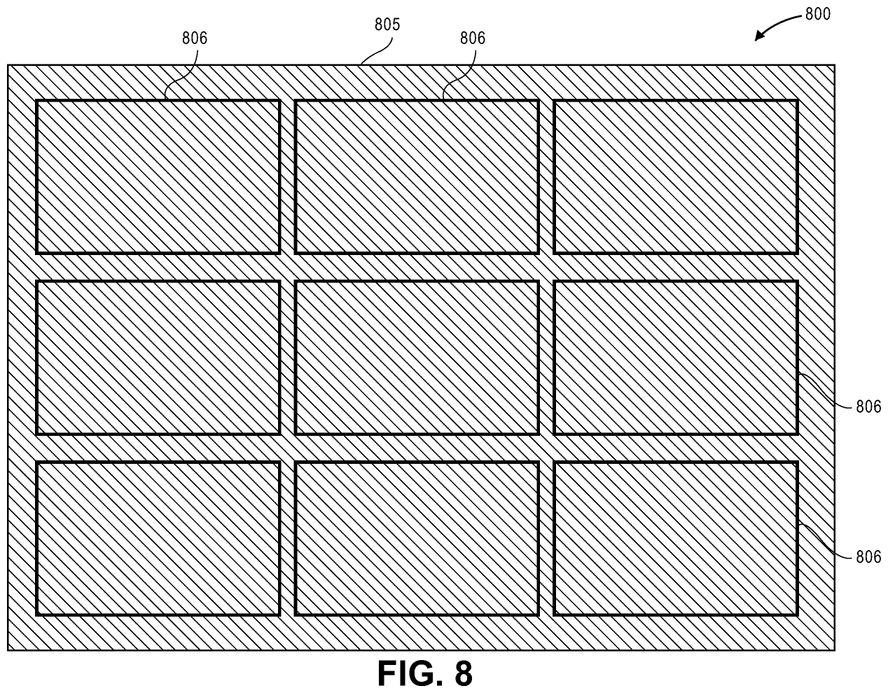

FIG. 8 illustrates an example of a substrate surface onto which grooves are to be formed in the creation of multiple packages, in accordance with embodiments. Diagram 800 may show a substrate 805 on which multiple interposer substrates 806 may be formed that may include features of embodiments described herein.

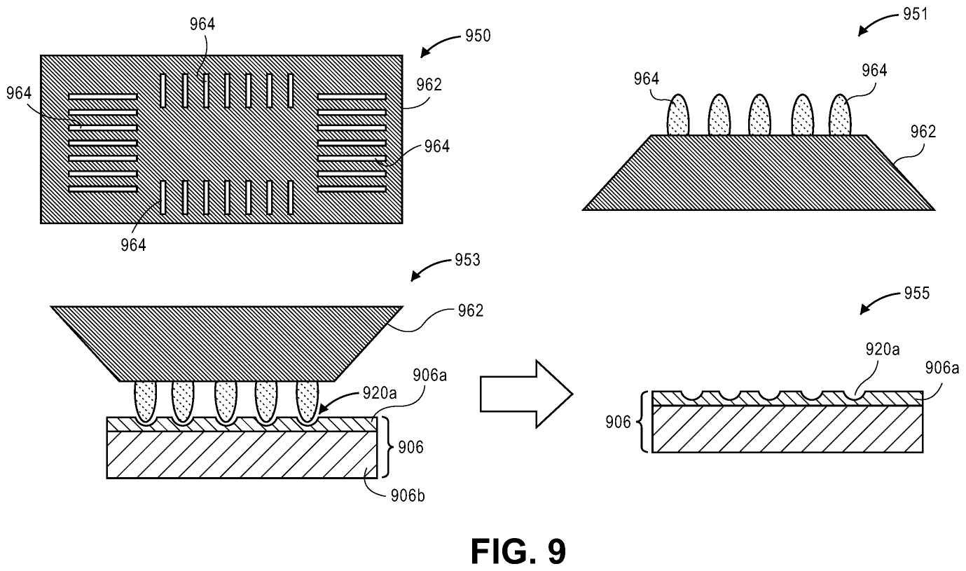

FIG. 9 illustrates examples of creating and using a rod array jig to create grooves in the substrate as a part of creating multiple packages, in accordance with embodiments. Diagram 950 is a rod array jig that includes a plate 962 that may include a plurality of rods 964 embedded into the plate 962. In embodiments, the rods 964 may have various shapes including round, elliptical, oblong, or other shapes that correspond to the shape of a groove, such as groove 920a to be made into a substrate 906. The rods 964 may be positioned in various orientations, including angled orientations not shown, or with various spacing between the rods 964 depending on the flow direction of an epoxy on a final substrate 906.

Diagram 951 shows a side view of plate 962 and the embedded plurality of rods 964. Diagram 953 shows the plate 962 and embedded plurality of rods 964 being pressed into a solder resist layer 906a of a substrate 906. In embodiments, the substrate 906 may have other layers such as a copper layer 906b. Diagram 955 shows the resulting substrate 906 that includes the grooves 920a. In particular, a groove 920a may be made into a solder resist layer 906a of the substrate 906.

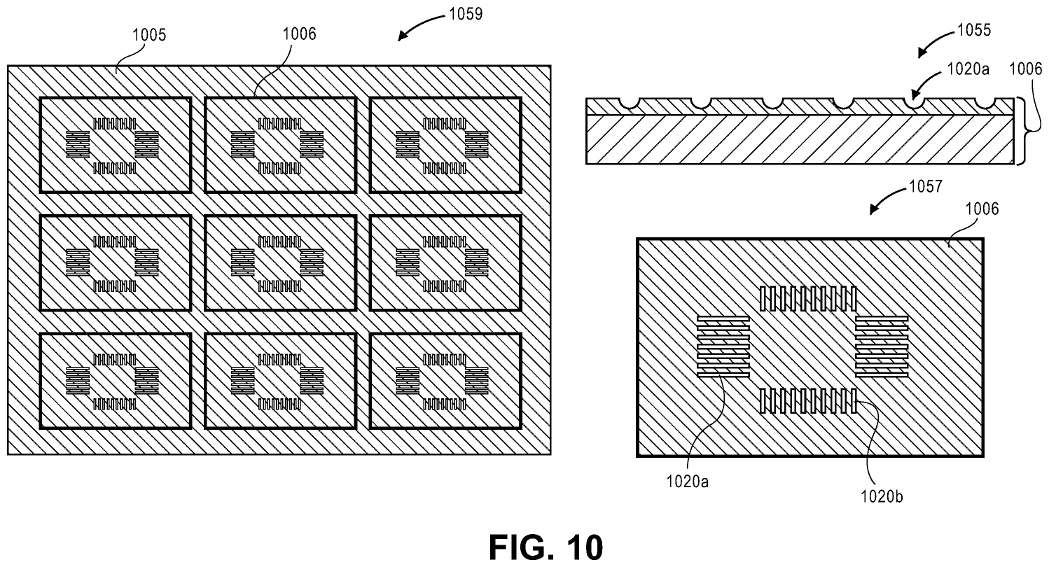

FIG. 10 shows multiple views of a solder resist substrate with grooves resulting from the use of a rod array jig in the creation of multiple packages, in accordance with embodiments. Diagram 1055, which may be similar to diagram 955 of FIG. 9, shows a substrate that includes grooves 1020a in a substrate 1006, which may be similar to substrate 906 of FIG. 9. Diagram 1057 shows a top-down view of the substrate 1006 that includes grooves 1020a, 1020b. Diagram 1059, which may be similar to diagram 800 of FIG. 8, shows the application of a rod array jig 950 to a substrate 1005, which may be similar to substrate 805 of FIG. 8. As a result of this application, a plurality of interposer substrates 1006 may be created each having grooves 1020a, 1020b.

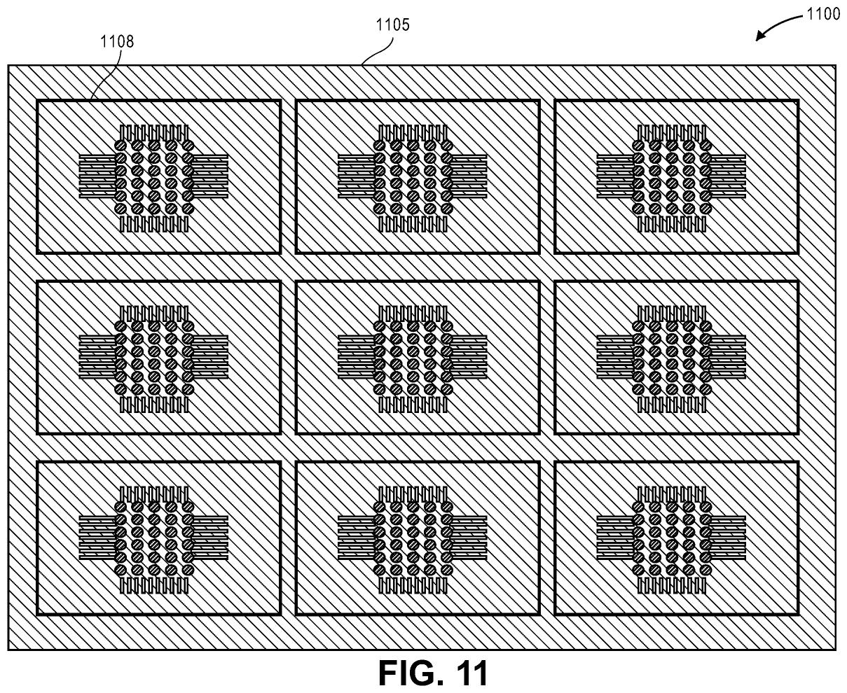

FIG. 11 shows a top-down view of the solder resist substrate after a developing process in the creation of multiple packages, in accordance with embodiments. Diagram 1100, which may be similar to diagram 1059 of FIG. 10, shows a substrate 1105, which may be similar to substrate 1005 of FIG. 10, after a polyethylene terephthalate (PET), solder resist exposure, and/or developing process has been applied to the substrate 1105. As a result of this process, solder balls 1108 may be applied to the substrate 1105. In other embodiments, bump pads (not shown) may also be applied.

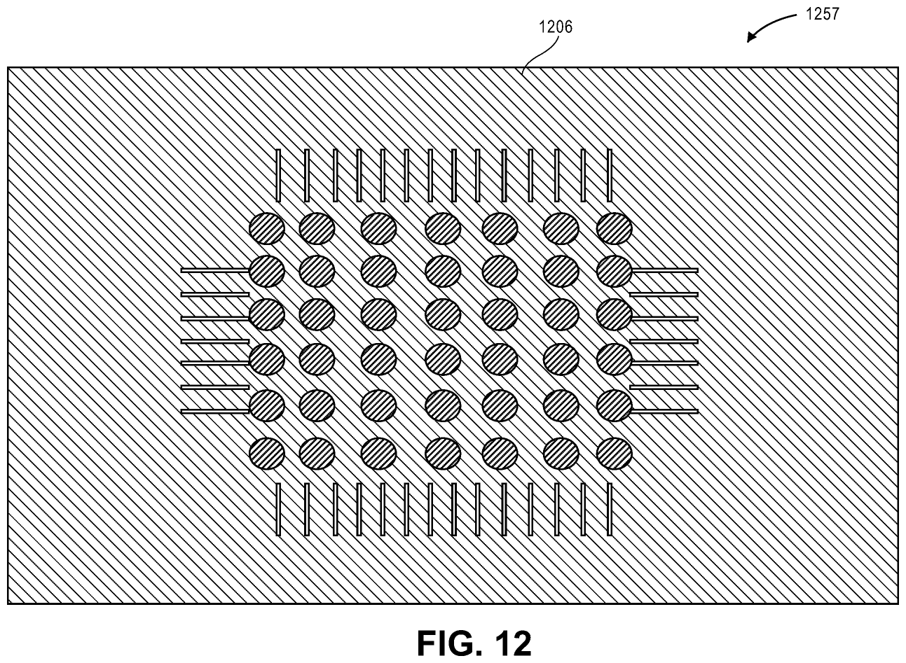

FIG. 12 shows a top-down view of an interposer patch attach area of an example package, in accordance with embodiments. Diagram 1257, which may be similar to diagram 1057 of FIG. 10, shows the result of surface finish plating and backend processes for a single interposer substrate 1206, which may be similar to interposer substrate 1108 of FIG. 11.

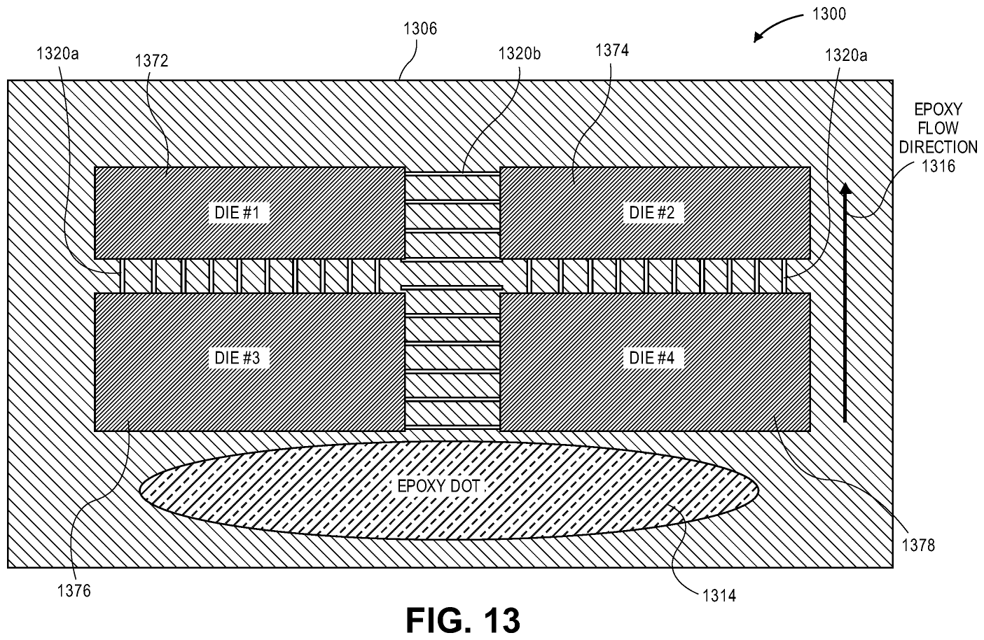

FIG. 13 shows a top-down view of a solder resist surface with grooves, multiple dies, and epoxy dot, in accordance with embodiments. Diagram 1300 shows an example of embodiments described herein applied to multichip package design. A substrate 1306, which may be similar to substrate 206 of FIG. 2, may have a plurality of grooves 1320a, 1320b formed in the substrate 1306. A plurality of dies 1372, 1374, 1376, 1378 may be attached to the substrate 1306. The epoxy 1314 is to flow in the epoxy flow direction 1316 to fill in underneath the dies 1372, 1374, 1376, 1378, with the speed of the epoxy 1314 influenced by the grooves 1320a, 1320b on the substrate 1306. As a result, depending upon the layout of the grooves 1320a, 1320b, the epoxy 1314 will underfill the dies without creating any epoxy voids after the epoxy 1314 cures.

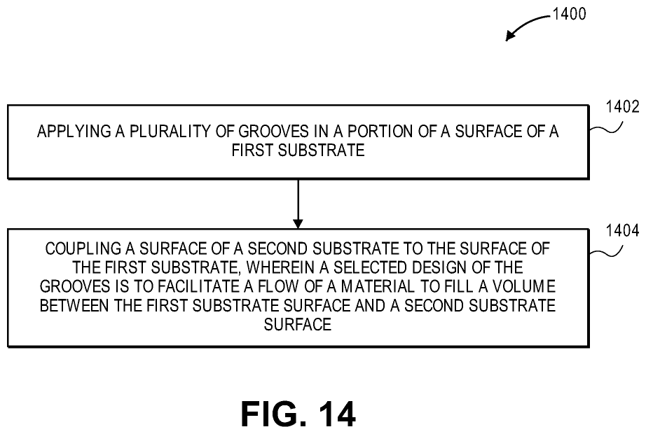

FIG. 14 illustrates an example process to couple two substrates with a flow of material between them, in accordance with embodiments. In embodiments, process 1400 may be performed by one or more of the techniques, processes, or actions described with respect to FIGS. 1A-13.

At block 1402, the process may include applying a plurality of grooves in a portion of a surface of a first substrate. In embodiments, the first substrate may be an interposer substrate 106 of FIG. 1A, a substrate 805 of FIG. 8, or may any other substrate over which the material, such as an epoxy 114 of FIG. 1B may flow. In embodiments, the first substrate may include features, such as a BGA 708a or bump pads 708b of FIG. 7, around which the material may flow. In embodiments, the grooves may be pressed into the first substrate using a jig 950 of FIG. 9 that includes an array of rods 964 that may be pressed into a substrate 906. In embodiments, the grooves may be pressed into a solder resist 906a layer of the substrate 906.

At block 1404, the process may further include coupling a surface of a second substrate to the surface of the first substrate, wherein a selected design of the grooves is to facilitate a flow of a material to fill a volume between the first substrate surface and a second substrate surface. In embodiments, the second substrate may be a patch substrate 102 of FIG. 1A, that may have a die 104 attached to the patch substrate 102. In embodiments, the first substrate surface and the second substrate surface may be coupled using solder balls 108, which may be configured in a BGA 708a configuration or as bump pads 708b of FIG. 7. The first substrate surface and the second substrate surface may not be coplanar, as shown by the spaces 110, 112 between patch substrate 102 and interposer substrate 106 of FIG. 1A.

In embodiments, grooves 220a, 220b may be included in the first substrate surface and directions to either facilitate the speeding up of epoxy 214 flow, for example by orienting grooves 220a in a direction of the epoxy flow direction 216 or to facilitate the slowing of epoxy 214 flow by orienting grooves 220b orthogonally to the direction of epoxy flow direction 216 in an epoxy flow direction 216. In embodiments, the grooves 220a, 220b may be in various orientations, sizes, widths, depths, shapes and spacing, including orientations not parallel to or perpendicular to an epoxy flow direction 216.

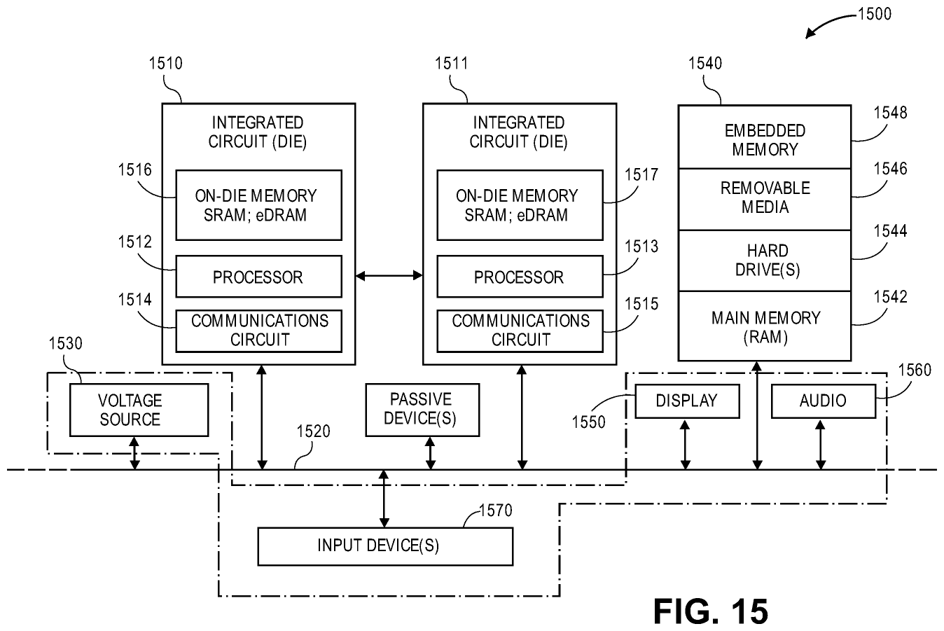

FIG. 15 is a schematic of a computer system 1500, in accordance with an embodiment of the present invention. The computer system 1500 (also referred to as the electronic system 1500) as depicted can embody a package that includes two coupled substrates with material floating between the substrates, according to any of the several disclosed embodiments and their equivalents as set forth in this disclosure. The computer system 1500 may be a mobile device such as a netbook computer. The computer system 1500 may be a mobile device such as a wireless smart phone. The computer system 1500 may be a desktop computer. The computer system 1500 may be a hand-held reader. The computer system 1500 may be a server system. The computer system 1500 may be a supercomputer or high-performance computing system.

In an embodiment, the electronic system 1500 is a computer system that includes a system bus 1520 to electrically couple the various components of the electronic system 1500. The system bus 1520 is a single bus or any combination of busses according to various embodiments. The electronic system 1500 includes a voltage source 1530 that provides power to the integrated circuit 1510. In some embodiments, the voltage source 1530 supplies current to the integrated circuit 1510 through the system bus 1520.

The integrated circuit 1510 is electrically coupled to the system bus 1520 and includes any circuit, or combination of circuits according to an embodiment. In an embodiment, the integrated circuit 1510 includes a processor 1512 that can be of any type. As used herein, the processor 1512 may mean any type of circuit such as, but not limited to, a microprocessor, a microcontroller, a graphics processor, a digital signal processor, or another processor. In an embodiment, the processor 1512 includes, or is coupled with, a patterned thin film capacitor, as disclosed herein. In an embodiment, SRAM embodiments are found in memory caches of the processor. Other types of circuits that can be included in the integrated circuit 1510 are a custom circuit or an application-specific integrated circuit (ASIC), such as a communications circuit 1514 for use in wireless devices such as cellular telephones, smart phones, pagers, portable computers, two-way radios, and similar electronic systems, or a communications circuit for servers. In an embodiment, the integrated circuit 1510 includes on-die memory 1516 such as static random-access memory (SRAM). In an embodiment, the integrated circuit 1510 includes embedded on-die memory 1516 such as embedded dynamic random-access memory (eDRAM).

In an embodiment, the integrated circuit 1510 is complemented with a subsequent integrated circuit 1511. Useful embodiments include a dual processor 1513 and a dual communications circuit 1515 and dual on-die memory 1517 such as SRAM. In an embodiment, the dual integrated circuit 1510 includes embedded on-die memory 1517 such as eDRAM.

In an embodiment, the electronic system 1500 also includes an external memory 1540 that in turn may include one or more memory elements suitable to the particular application, such as a main memory 1542 in the form of RAM, one or more hard drives 1544, and/or one or more drives that handle removable media 1546, such as diskettes, compact disks (CDs), digital variable disks (DVDs), flash memory drives, and other removable media known in the art. The external memory 1540 may also be embedded memory 1548 such as the first die in a die stack, according to an embodiment.

In an embodiment, the electronic system 1500 also includes a display device 1550, an audio output 1560. In an embodiment, the electronic system 1500 includes an input device such as a controller 1570 that may be a keyboard, mouse, trackball, game controller, microphone, voice-recognition device, or any other input device that inputs information into the electronic system 1500. In an embodiment, an input device 1570 is a camera. In an embodiment, an input device 1570 is a digital sound recorder. In an embodiment, an input device 1570 is a camera and a digital sound recorder.

As shown herein, the integrated circuit 1510 can be implemented in a number of different embodiments, including a package substrate having a patterned thin film capacitor, according to any of the several disclosed embodiments and their equivalents, an electronic system, a computer system, one or more methods of fabricating an integrated circuit, and one or more methods of fabricating an electronic assembly that includes a package substrate having a patterned thin film capacitor, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having patterned thin film capacitor embodiments and their equivalents. A foundation substrate may be included, as represented by the dashed line of FIG. 15. Passive devices may also be included, as is also depicted in FIG. 15.

The following paragraphs describe examples of various embodiments.

Example 1 may be an apparatus comprising: a first substrate with a surface that is substantially planar; and a plurality of grooves in a portion of the first substrate surface, wherein a selected design of the grooves is to facilitate a flow of a material to fill a volume between the first substrate surface and a second substrate surface created in response to the second substrate surface coupled with the first substrate surface.

Example 2 may include the apparatus of example 1, wherein the second substrate surface is to be coupled with the first substrate surface via a BGA.

Example 3 may include the apparatus of example 1, wherein the selected design of the grooves further includes depth, spacing, profile, or orientation of the grooves.

Example 4 may include the apparatus of example 1, further comprising the second substrate surface; wherein the second substrate surface is coupled to the first substrate surface; and wherein the flow of material is based at least upon capillary action created by a proximity of the second substrate surface to the first substrate surface.

Example 5 may include the apparatus of example 1, further comprising the material.

Example 6 may include the apparatus of example 5, wherein the material is placed on a portion of the first substrate surface.

Example 7 may include the apparatus of example 1, wherein the grooves in the first substrate surface include multiple groups of substantially parallel grooves in the first substrate surface; and wherein an orientation of a group of the substantially parallel grooves with respect to the flow of epoxy is to increase or to decrease the flow of material into a volume proximate to the group of grooves and between the first substrate surface and the second substrate surface.

Example 8 may include the apparatus of example 7, wherein the volume proximate to the group of grooves has a height h between the first substrate surface and the second substrate surface.

Example 9 may include the apparatus of example 7, wherein, when h is less than a first value, the group of grooves on the respective first substrate surfaces are substantially perpendicular to the flow of epoxy; and wherein, when h is greater than a second value, the group of grooves on the respective first substrate surfaces are substantially parallel to the flow of epoxy.

Example 10 may include the apparatus of any one of examples 1-9, wherein the material is an epoxy.

Example 11 may be a method comprising: applying a plurality of grooves in a portion of a surface of a first substrate; coupling a surface of a second substrate to the surface of the first substrate; and wherein a selected design of the grooves is to facilitate a flow of a material to fill a volume between the first substrate surface and a second substrate surface.

Example 12 may include the method of example 11, further comprising placing the material on a portion of the first substrate.

Example 13 may include the method of example 11, wherein coupling in the surface of the second substrate to the surface of the first substrate further includes coupling the surface of the second substrate to the surface of the first substrate via a BGA.

Example 14 may include the method of example 11, wherein applying a plurality of grooves in a portion of the surface of the first substrate further includes applying a plurality of grooves in an orientation to increase or to decrease the flow of material into a volume proximate to the plurality of grooves and between the first substrate surface and the second substrate surface.

Example 15 may include the method of example 14, wherein the volume proximate to the group of grooves has a height h between the first substrate surface and the second substrate surface.

Example 16 may include the method of example 14, further comprising, upon h being less than a first value, orienting the group of grooves on the respective first substrate surfaces to be substantially perpendicular to the flow of material.

Example 17 may include the method of example 14, further comprising, upon h being greater than a second value, orienting the group of grooves on the respective first substrate surfaces to be substantially parallel to the flow of material.

Example 18 may be an apparatus comprising: means for applying a plurality of grooves in a portion of a surface of a first substrate; means for coupling a surface of a second substrate to the surface of the first substrate; and wherein a selected design of the grooves is to facilitate a flow of a material to fill a volume between the first substrate surface and a second substrate surface.

Example 19 may include the apparatus of example 18, wherein applying a plurality of grooves in a portion of the surface of the first substrate further includes: means for applying a plurality of grooves in an orientation to increase or to decrease the flow of material into a volume proximate to the plurality of grooves and between the first substrate surface and the second substrate surface.

Example 20 may include the apparatus of example 19, wherein the volume proximate to the group of grooves has a height h between the first substrate surface and the second substrate surface; and further comprising: upon h being less than a first value, means for orienting the group of grooves on the respective first substrate surfaces to be substantially perpendicular to the flow of material; and upon h being greater than a first value, means for orienting the group of grooves on the respective first substrate surfaces to be substantially parallel to the flow of material.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. An apparatus comprising:
a first substrate with a surface that is substantially planar; and
a plurality of grooves in a portion of the first substrate surface, wherein a selected design of the grooves is to facilitate a flow of a material to fill a volume between the first substrate surface and a second substrate surface created in response to the second substrate surface coupled with the first substrate surface.

2. The apparatus of claim 1, wherein the second substrate surface is to be coupled with the first substrate surface via a ball grid array (BGA).

3. The apparatus of claim 1, wherein the selected design of the grooves further includes depth, spacing, profile, or orientation of the grooves.

4. The apparatus of claim 1, further comprising the second substrate surface;
wherein the second substrate surface is coupled to the first substrate surface; and
wherein the flow of material is based at least upon capillary action created by a proximity of the second substrate surface to the first substrate surface.

5. The apparatus of claim 1, further comprising the material.

6. The apparatus of claim 5, wherein the material is placed on a portion of the first substrate surface.

7. The apparatus of claim 1, wherein the grooves in the first substrate surface include multiple groups of substantially parallel grooves in the first substrate surface; and
wherein an orientation of a group of the substantially parallel grooves with respect to the flow of epoxy is to increase or to decrease the flow of material into a volume proximate to the group of grooves and between the first substrate surface and the second substrate surface.

8. The apparatus of claim 7, wherein the volume proximate to the group of grooves has a height h between the first substrate surface and the second substrate surface.

9. The apparatus of claim 7, wherein, when h is less than a first value, the group of grooves on the respective first substrate surfaces are substantially perpendicular to the flow of epoxy; and
wherein, when h is greater than a second value, the group of grooves on the respective first substrate surfaces are substantially parallel to the flow of epoxy.

10. The apparatus of claim 1, wherein the material is an epoxy.

11. A method comprising:
applying a plurality of grooves in a portion of a surface of a first substrate;
coupling a surface of a second substrate to the surface of the first substrate; and
wherein a selected design of the grooves is to facilitate a flow of a material to fill a volume between the first substrate surface and a second substrate surface.

12. The method of claim 11, further comprising placing the material on a portion of the first substrate.

13. The method of claim 11, wherein coupling in the surface of the second substrate to the surface of the first substrate further includes coupling the surface of the second substrate to the surface of the first substrate via a ball grid array (BGA).

14. The method of claim 11, wherein applying a plurality of grooves in a portion of the surface of the first substrate further includes applying a plurality of grooves in an orientation to increase or to decrease the flow of material into a volume proximate to the plurality of grooves and between the first substrate surface and the second substrate surface.

15. The method of claim 14, wherein the volume proximate to the group of grooves has a height h between the first substrate surface and the second substrate surface.

16. The method of claim 14, further comprising, upon h being less than a first value, orienting the group of grooves on the respective first substrate surfaces to be substantially perpendicular to the flow of material.

17. The method of claim 14, further comprising, upon h being greater than a second value, orienting the group of grooves on the respective first substrate surfaces to be substantially parallel to the flow of material.

18. An apparatus comprising:
means for applying a plurality of grooves in a portion of a surface of a first substrate;
means for coupling a surface of a second substrate to the surface of the first substrate; and
wherein a selected design of the grooves is to facilitate a flow of a material to fill a volume between the first substrate surface and a second substrate surface.

19. The apparatus of claim 18, wherein applying a plurality of grooves in a portion of the surface of the first substrate further includes:
means for applying a plurality of grooves in an orientation to increase or to decrease the flow of material into a volume proximate to the plurality of grooves and between the first substrate surface and the second substrate surface.

20. The apparatus of claim 19, wherein the volume proximate to the group of grooves has a height h between the first substrate surface and the second substrate surface; and
further comprising:
upon h being less than a first value, means for orienting the group of grooves on the respective first substrate surfaces to be substantially perpendicular to the flow of material; and
upon h being greater than a first value, means for orienting the group of grooves on the respective first substrate surfaces to be substantially parallel to the flow of material.
